(19) United States
(12) Patent Application Publication
(10) Pub. No.: US 2015/0346478 A1
(43) Pub. Date: Dec. 3, 2015

(54) Protection of Thin Film Transistors in a Display Element Array from Visible and Ultraviolet Light

(71) Applicant: QUALCOMM MEMS Technologies, Inc., San Diego, CA (US)

(72) Inventors: Cheonhong Kim, San Diego, CA (US); Tsongming Kao, Sunnyvale, CA (US); Jian Ma, Carlsbad, CA (US); Lixia Zhou, Milpitas, CA (US); Tallis Young Chang, San Diego, CA (US); Shu-Jhih Chen, Taoyuan County (TW); John Hyunchul Hong, San Clemente, CA (US)

(21) Appl. No.: 14/500,690

(22) Filed: Sep. 29, 2014

Related U.S. Application Data
(60) Provisional application No. 62/005,587, filed on May 30, 2014.

(51) Int. Cl. G02B 26/00; G02B 5/00; G02B 5/20; H01L 27/12

(52) U.S. Cl. CPC G02B 26/001; H01L 27/1248; H01L 27/1259; G02B 5/003; G02B 5/208

(57) ABSTRACT

A display assembly includes an array of display elements disposed between a first substrate and a second substrate, the array of display elements including one or more thin film transistors (TFTs). A black mask arrangement is disposed between the first substrate and the second substrate, the black mask arrangement being configured to prevent light entering the display assembly from reaching the TFTs.

### CROSS-REFERENCE TO RELATED APPLICATIONS

This disclosure claims priority to U.S. Provisional Patent Application No. 62/005,587 (Attorney Docket No. QUALP260PUS/144439P1), filed May 30, 2014, entitled “PROTECTION OF THIN FILM TRANSISTORS IN A DISPLAY ELEMENT ARRAY FROM VISIBLE AND ULTRAVIOLET LIGHT,” and assigned to the assignee hereof. The disclosure of the prior application is considered part of and is incorporated by reference in its entirety in this patent application.

### TECHNICAL FIELD

This disclosure relates to electromechanical systems and devices. More specifically, the disclosure relates to an interferometric modulator (IMOD) display element array, including techniques for protecting thin film transistors (TFTs) associated with the display element array from damage caused by ultraviolet and visible light.

### DESCRIPTION OF THE RELATED TECHNOLOGY

Electromechanical systems (EMS) include devices having electrical and mechanical elements, actuators, transducers, sensors, optical components such as mirrors and optical films, and electronics. EMS devices or elements can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of EMS device is called an interferometric modulator (IMOD). The term IMOD or interferometric light modulator refers to a device that selectively absorbs and/or reflects light using the principles of optical interference. In some implementations, an IMOD display element may include a pair of conductive plates, one or both of which may be transparent and/or reflective, wholly or in part, and capable of relative motion upon application of an appropriate electrical signal. For example, one plate may include a stationary layer deposited over, on or supported by a substrate and the other plate may include a reflective membrane separated from the stationary layer by an air gap. The position of one plate in relation to another can change the optical interference of light incident on the IMOD display element. IMOD-based display devices have a wide range of applications, and are anticipated to be used in improving existing products and creating new products, especially those with display capabilities.

### SUMMARY

The systems, methods and devices of this disclosure each have several innovative aspects, no single one of which is solely responsible for the desirable attributes disclosed herein.

One innovative aspect of the subject matter described in this disclosure relates to techniques for protecting light-sensitive circuitry, particularly thin film transistors associated with an IMOD display from damage that may otherwise result from exposure to ultraviolet and visible light.

According to some implementations, a display assembly includes an array of display elements disposed between a first substrate and a second substrate one or more thin film transistors (TFTs) disposed between the first substrate and the second substrate, and a black mask arrangement. The black mask arrangement is disposed between the first substrate and the second substrate, and is configured to prevent light entering the display assembly from reaching the TFTs.

In some examples, the first substrate may be a transparent front layer of the display assembly and the second substrate may be a backplate of the display assembly. At least a first portion of the TFTs may be disposed on an inner surface of the transparent front layer, outside a perimeter of the array of display elements. The display assembly may include an ultraviolet (UV) absorbing passivation layer disposed between the TFTs and the backplate.

In some examples, the black mask arrangement may include a plurality of black mask (BM) stacks. At least a first BM stack may be configured to protect the TFTs from light entering the display assembly through the first substrate. The black mask arrangement may include a light blocking layer configured to protect the TFTs from light entering the display assembly through the second substrate. The light blocking layer may include a metal layer. The display assembly may include an insulating layer between at least one BM stack and at least a portion of the TFTs.

In some examples, the array of display elements may include an array of interferometric modulator (IMOD) display elements. In some examples, the black mask arrangement may be configured to prevent the light entering the display assembly from reaching the TFTs irrespective of whether the light enters the display assembly through the first substrate or through the second substrate of the display assembly.

In some examples, the first substrate and the second substrate may be secured together to form a sandwich-like assembly, the assembly being sealed, proximate to a perimeter of the assembly, by way of a sealant. The display assembly may include a filter disposed between an ultraviolet (UV) light source and the TFTs, the filter being configured to filter out UV light other than a wavelength which is absorbed by the sealant. The sealant may at least partially encircle the array.

In some examples, the black mask arrangement may include a number of black mask (BM) stacks that are disposed at separate selected locations between the TFTs and one or both of the first substrate and the second substrate; and the separate selected locations are selected with reference to respective locations of portions of the TFTs. The array of display elements may include an array of interferometric modulator (IMOD) display elements, each IMOD display element including a respective reflective movable layer. At least one of the BM stacks may be disposed, between the IMOD display elements and the first substrate, proximate to one of the respective reflective movable layers. The BM stacks, in cooperation with the reflective movable layers, may prevent light, having passed through the first substrate, from reaching the TFTs. At least a portion of the TFTs may be disposed between the reflective movable layers and the second substrate. The BM stacks may include conductive layers that are configured to function as an electrical bussing layer.

In some implementations, a method for fabricating a display assembly includes disposing an array of display elements and a black mask arrangement between a transparent front layer of the display assembly and a backplate of the display assembly, the display assembly including one or more thin film transistors (TFTs) disposed between the transparent front layer and the backplate. The black mask arrangement is configured to prevent light entering the display assembly from reaching the TFTs.

In some examples, the method may include securing together the transparent front layer and the backplate to form a sandwich-like assembly, sealing the assembly, proximate to a perimeter of the assembly, with a sealant; and curing the sealant by irradiating the assembly with ultraviolet (UV) light. In some examples, the method may include an ultraviolet self-assembled monolayer removal UV process. In some examples, the black mask arrangement may include a number of black mask (BM) stacks that are disposed at separate selected locations between the TFTs and one or both of the first substrate and the second substrate. The array of display elements may include an array of interferometric modulator (IMOD) display elements each IMOD display element including a respective reflective movable layer. At least one of the BM stacks may be disposed, between the IMOD display elements and the first substrate, proximate to one of the reflective movable layers.

In some implementations, a display assembly includes an array of interferometric modulator (IMOD) display elements disposed between a transparent front layer of the display assembly and a backplate of the display assembly, the display assembly including one or more thin film transistors (TFTs) disposed between the transparent front layer and the backplate. An ultraviolet (UV) light absorbing layer is disposed between the TFTs and the backplate, the UV light absorbing layer being configured to absorb a portion of UV light within a selected wavelength range.

In some examples, the UV-absorbing layer may have a band-gap energy less than about 2.7 eV. In some examples, the UV-absorbing layer may include one or more of a Si-rich silicon nitride film, a TiOx film and a TiOx—ZrOx hybrid film. In some examples, the UV-absorbing layer may be an insulator.

In some implementations, a display assembly includes an array of interferometric modulator (IMOD) display elements disposed between a transparent front layer of the display assembly and a backplate of the display assembly, the array of display elements including one or more thin film transistors (TFTs) disposed between the transparent front layer and the backplate. A black mask arrangement, is disposed between the first substrate and the second substrate, the black mask arrangement being configured to prevent light entering the display assembly from reaching the TFTs, irrespective of whether the light enters the display assembly through the transparent front layer of the display assembly or through the backplate of the display assembly.

In some examples, the black mask arrangement may include (i) a plurality of black mask (BM) stacks, at least a first BM stack configured to protect the TFTs from light entering the display assembly through the first substrate; and (ii) a light blocking layer configured to protect the TFTs from light entering the display assembly through the second substrate. In some examples, the display assembly may include a filter disposed between an ultraviolet (UV) light source and the TFTs, the filter being configured to filter out UV light other than a wavelength which is absorbed by the sealant. In some examples, each IMOD display element may include a respective reflective movable layer; and at least one of the BM stacks may be disposed, between the IMOD display elements and the first substrate, proximate to one of the respective reflective movable layers.

### BRIEF DESCRIPTION OF THE DRAWINGS

FIG. 1 is an isometric view illustration depicting two adjacent interferometric modulator (IMOD) display elements in a series or array of display elements of an IMOD display device.

FIG. 2 is a system block diagram illustrating an electronic device incorporating an IMOD-based display including a three element by three element array of IMOD display elements.

FIG. 3 is a graph illustrating movable reflective layer position versus applied voltage for an IMOD display element.

FIG. 4 is a table illustrating various states of an IMOD display element when various common and segment voltages are applied.

FIG. 5A is an illustration of a frame of display data in a three element by three element array of IMOD display elements displaying an image.

FIG. 5B is a timing diagram for common and segment signals that may be used to write data to the display elements illustrated in FIG. 5A.

FIGS. 6A and 6B are schematic exploded partial perspective views of a portion of an electromechanical systems (EMS) package including an array of EMS elements and a backplate.

FIGS. 7A and 7B illustrate an elevation view of an arrangement of a partially assembled IMOD display.

FIG. 8 illustrates an elevation view of an arrangement of a partially assembled IMOD display, according to an implementation.

FIG. 9 illustrates a cross-section of an IMOD display element according to an implementation.

FIG. 10 illustrates an implementation of a partially assembled IMOD display where a black mask arrangement protects TFTs from light impingement.

FIG. 11 illustrates an implementation of a partially assembled IMOD display where an ultraviolet (UV) light absorbing layer protects the TFTs from light impingement.

FIG. 12 illustrates an example of performance of a UV light band-pass filter, according to an implementation.

FIG. 13 is a flow diagram illustrating an example of a manufacturing process for a display.

FIGS. 14A and 14B are system block diagrams illustrating a display device that includes a plurality of IMOD display elements.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device, apparatus, or system that can be configured to display an image, whether in motion (such as video) or stationary (such as still images), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, global positioning system (GPS) receivers/navigators, cameras, digital media players (such as MP3 players), camcorders, game consoles, wrist watches, clocks, calculators, television monitors, flat panel displays, electronic reading devices (e.g., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS) applications including microelectromechanical systems (MEMS) applications, as well as non-EMS applications), aesthetic structures (such as display of images on a piece of jewelry or clothing) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Various implementations disclosed herein include techniques for protecting light-sensitive circuitry, particularly thin film transistors (TFTs) associated with a display (e.g., an IMOD-based display) from damage that may otherwise result from exposure to ultraviolet and visible light. For example, during fabrication processes of a display, irradiation of a display panel with ultraviolet (UV) light may be required in connection with, for example, curing a sealant.

Particular implementations of the subject matter described in this disclosure can be implemented to realize one or more of the following potential advantages. By strategically locating portions of a black mask arrangement and/or a filtering layer so as to prevent light from reaching the TFTs, the display fabrication process can be simplified. Risk to damage of the TFTs by the UV light used in the curing process is substantially decreased. In addition, the masking arrangement can continue to protect the TFTs from visible and UV light during the lifetime of the display, thus improving the reliability of the TFTs.

An example of a suitable EMS or MEMS device or apparatus, to which the described implementations may apply, is a reflective display device. Reflective display devices can incorporate interferometric modulator (IMOD) display elements that can be implemented to selectively absorb and/or reflect light incident thereon using principles of optical interference. IMOD display elements can include a partial optical absorber, a reflector that is movable with respect to the absorber, and an optical resonant cavity defined between the absorber and the reflector. In some implementations, the reflector can be moved to two or more different positions, which can change the size of the optical resonant cavity and thereby affect the reflectance of the IMOD. The reflectance spectra of IMOD display elements can create fairly broad spectral bands that can be shifted across the visible wavelengths to generate different colors. The position of the spectral band can be adjusted by changing the thickness of the optical resonant cavity. One way of changing the optical resonant cavity is by changing the position of the reflector with respect to the absorber.

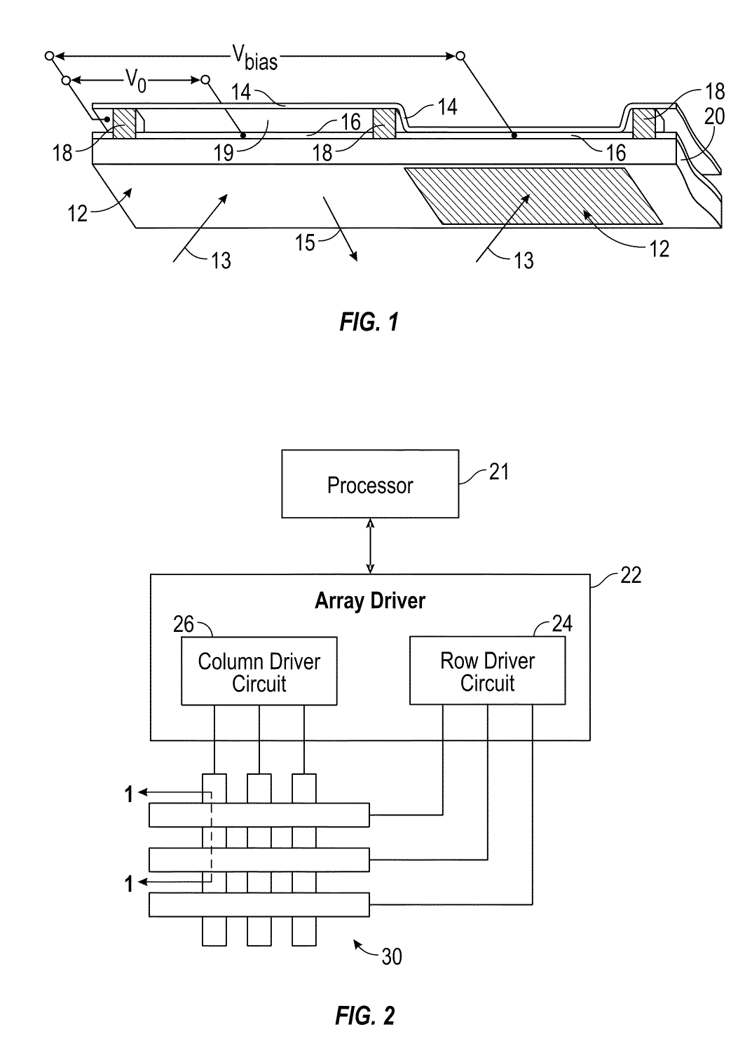

FIG. 1 is an isometric view illustration depicting two adjacent interferometric modulator (IMOD) display elements in a series or array of display elements of an IMOD display device. The IMOD display device includes one or more interferometric EMS, such as MEMS, display elements. In these devices, the interferometric MEMS display elements can be configured in either a bright or dark state. In the bright (“relaxed,” “open” or “on,” etc.) state, the display element reflects a large portion of incident visible light. Conversely, in the dark (“actuated,” “closed” or “off,” etc.) state, the display element reflects little incident visible light. MEMS display elements can be configured to reflect predominantly at particular wavelengths of light allowing for a color display in addition to black and white. In some implementations, by using multiple display elements, different intensities of color primaries and shades of gray can be achieved.

The IMOD display device can include an array of IMOD display elements which may be arranged in rows and columns. Each display element in the array can include at least a pair of reflective and semi-reflective layers, such as a movable reflective layer (i.e., a movable layer, also referred to as a mechanical layer) and a fixed partially reflective layer (i.e., a stationary layer), positioned at a variable and controllable distance from each other to form an air gap (also referred to as an optical gap, cavity or optical resonant cavity). The movable reflective layer may be moved between at least two positions. For example, in a first position, i.e., a relaxed position, the movable reflective layer can be positioned at a distance from the fixed partially reflective layer. In a second position, i.e., an actuated position, the movable reflective layer can be positioned more closely to the partially reflective layer. Incident light that reflects from the two layers can interfere constructively and/or destructively depending on the position of the movable reflective layer and the wavelength(s) of the incident light, producing either an overall reflective or non-reflective state for each display element. In some implementations, the display element may be in a reflective state when unactuated, reflecting light within the visible spectrum, and may be in a dark state when actuated, absorbing and/or destructively interfering light within the visible range. In some other implementations, however, an IMOD display element may be in a dark state when unactuated, and in a reflective state when actuated. In some implementations, the introduction of an applied voltage can drive the display elements to change states. In some other implementations, an applied charge can drive the display elements to change states.

The depicted portion of the array in FIG. 1 includes two adjacent interferometric MEMS display elements in the form of IMOD display elements 12. In the display element 12 on the right (as illustrated), the movable reflective layer 14 is illustrated in an actuated position near, adjacent or touching the optical stack 16. The voltage V_{bias} applied across the display element 12 on the right is sufficient to move and also maintain the movable reflective layer 14 in the actuated position. In the display element 12 on the left (as illustrated), a movable reflective layer 14 is illustrated in a relaxed position at a distance (which may be predetermined based on design parameters) from an optical stack 16, which includes a partially reflective layer. The voltage V₀ applied across the display element 12 on the left is insufficient to cause actuation of the movable reflective layer 14 to an actuated position such as that of the display element 12 on the right.

In FIG. 1, the reflective properties of IMOD display elements 12 are generally illustrated with arrows indicating light 13 incident upon the IMOD display elements 12, and light 15 reflecting from the display element 12 on the left. Most of the light 13 incident upon the display elements 12 may be transmitted through the transparent substrate 20, toward the optical stack 16. A portion of the light incident upon the optical stack 16 may be transmitted through the partially reflective layer of the optical stack 16, and a portion will be reflected back through the transparent substrate 20. The portion of light 13 that is transmitted through the optical stack 16 may be reflected from the movable reflective layer 14, back toward (and through) the transparent substrate 20. Interference (constructive and/or destructive) between the light reflected from the partially reflective layer of the optical stack 16 and the light reflected from the movable reflective layer 14 will determine in part the intensity of wavelength(s) of light 15 reflected from the display element 12 on the viewing or substrate side of the device. In some implementations, the transparent substrate 20 can be a glass substrate (sometimes referred to as a glass plate or panel). The glass substrate may be or include, for example, a borosilicate glass, a soda lime glass, quartz, Pyrex, or other suitable glass material. In some implementations, the glass substrate may have a thickness of 0.3, 0.5 or 0.7 millimeters, although in some implementations the glass substrate can be thicker (such as tens of millimeters) or thinner (such as less than 0.3 millimeters). In some implementations, a non-glass substrate can be used, such as a polycarbonate, acrylic, polyethylene terephthalate (PET) or polyether ether ketone (PEEK) substrate. In such an implementation, the non-glass substrate will likely have a thickness of less than 0.7 millimeters, although the substrate may be thicker depending on the design considerations. In some implementations, a non-transparent substrate, such as a metal foil or stainless steel-based substrate can be used. For example, a reverse-IMOD-based display, which includes a fixed reflective layer and a movable layer which is partially transmissive and partially reflective, may be configured to be viewed from the opposite side of a substrate as the display elements 12 of FIG. 1 and may be supported by a non-transparent substrate.

The optical stack 16 can include a single layer or several layers. The layer(s) can include one or more of an electrode layer, a partially reflective and partially transmissive layer, and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals (e.g., chromium and/or molybdenum), semiconductors, and dielectrics. The partially reflective layer can be formed of one or more layers of materials, and each of the layers can be formed of a single material or a combination of materials. In some implementations, certain portions of the optical stack 16 can include a single semi-transparent thickness of metal or semiconductor which serves as both a partial optical absorber and electrical conductor, while different, electrically more conductive layers or portions (e.g., of the optical stack 16 or of other structures of the display element) can serve to bus signals between IMOD display elements. The optical stack 16 also can include one or more insulating or dielectric layers covering one or more conductive layers or an electrically conductive/partially absorptive layer.

In some implementations, at least some of the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of supports, such as the illustrated posts 18, and an intervening sacrificial material located between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be approximately less than 10,000 Angstroms (Å).

In some implementations, each IMOD display element, whether in the actuated or relaxed state, can be considered as a capacitor formed by the fixed and moving reflective layers. When no voltage is applied, the movable reflective layer 14 remains in a mechanically relaxed state, as illustrated by the display element 12 on the left in FIG. 1, with the gap 19 between the movable reflective layer 14 and optical stack 16. However, when a potential difference, i.e., a voltage, is applied to at least one of a selected row and column, the capacitor formed at the intersection of the row and column electrodes at the corresponding display element becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated display element 12 on the right in FIG. 1. The behavior can be the same regardless of the polarity of the applied potential difference. Though a series of display elements in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. In some implementations, the rows may be referred to as “common” lines and the columns may be referred to as “segment” lines, or vice versa. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 2 is a system block diagram illustrating an electronic device incorporating an IMOD-based display including a three element by three element array of IMOD display elements. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example a display array or panel 30. The cross section of the IMOD display device illustrated in FIG. 1 is shown by the lines 1-1 in FIG. 2. Although FIG. 2 illustrates a 3×3 array of IMOD display elements for the sake of clarity, the display array 30 may contain a very large number of IMOD display elements, and may have a different number of IMOD display elements in rows than in columns, and vice versa.

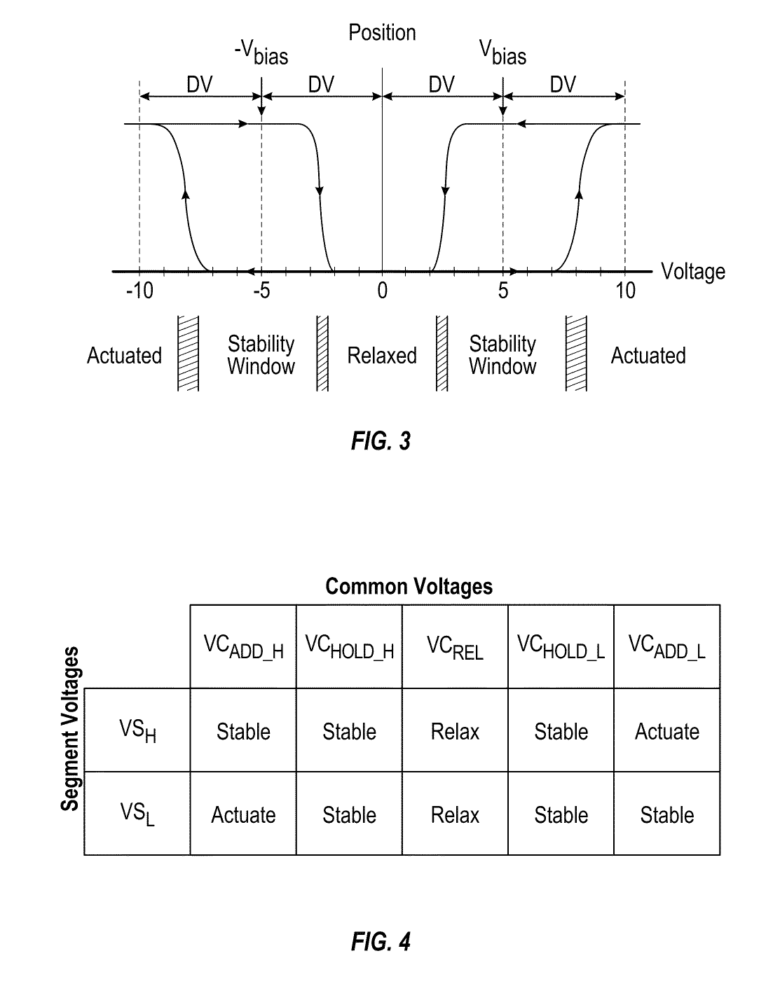

FIG. 3 is a graph illustrating movable reflective layer position versus applied voltage for an IMOD display element. For IMODs, the row/column (i.e., common/segment) write procedure may take advantage of a hysteresis property of the display elements as illustrated in FIG. 3. An IMOD display element may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3-7 volts, in the example of FIG. 3, exists where there is a window of applied voltage within which the element is stable in either the relaxed or actuated state. This is referred to herein as the “hysteresis window” or “stability window.” For a display array 30 having the hysteresis characteristics of FIG. 3, the row/column write procedure can be designed to address one or more rows at a time. Thus, in this example, during the addressing of a given row, display elements that are to be actuated in the addressed row can be exposed to a voltage difference of about 10 volts, and display elements that are to be relaxed can be exposed to a voltage difference of near zero volts. After addressing, the display elements can be exposed to a steady state or bias voltage difference of approximately 5 volts in this example, such that they remain in the previously strobed, or written, state. In this example, after being addressed, each display element sees a potential difference within the “stability window” of about 3-7 volts. This hysteresis property feature enables the IMOD display element design to remain stable in either an actuated or relaxed pre-existing state under the same applied voltage conditions. Since each IMOD display element, whether in the actuated or relaxed state, can serve as a capacitor formed by the fixed and moving reflective layers, this stable state can be held at a steady voltage within the hysteresis window without substantially consuming or losing power. Moreover, essentially little or no current flows into the display element if the applied voltage potential remains substantially fixed.

In some implementations, a frame of an image may be created by applying data signals in the form of “segment” voltages along the set of column electrodes, in accordance with the desired change (if any) to the state of the display elements in a given row. Each row of the array can be addressed in turn, such that the frame is written one row at a time. To write the desired data to the display elements in a first row, segment voltages corresponding to the desired state of the display elements in the first row can be applied on the column electrodes, and a first row pulse in the form of a specific “common” voltage or signal can be applied to the first row electrode. The set of segment voltages can then be changed to correspond to the desired change (if any) to the state of the display elements in the second row, and a second common voltage can be applied to the second row electrode. In some implementations, the display elements in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

The combination of segment and common signals applied across each display element (that is, the potential difference across each display element or pixel) determines the resulting state of each display element. FIG. 4 is a table illustrating various states of an IMOD display element when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

As illustrated in FIG. 4, when a release voltage VC_{REL} is applied along a common line, all IMOD display elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator display elements or pixels (alternatively referred to as a display element or pixel voltage) can be within the relaxation window (see FIG. 3, also referred to as a release window) both when the high segment voltage VS_{H} and the low segment voltage VS_{L} are applied along the corresponding segment line for that display element.

When a hold voltage is applied on a common line, such as a high hold voltage VC_{HOLD}_{_{—}}_{H} or a low hold voltage VC_{HOLD}_{_{—}}_{L}, the state of the IMOD display element along that common line will remain constant. For example, a relaxed IMOD display element will remain in a relaxed position, and an actuated IMOD display element will remain in an actuated position. The hold voltages can be selected such that the display element voltage will remain within a stability window both when the high segment voltage VS_{H} and the low segment voltage VS_{L} are applied along the corresponding segment line. Thus, the segment voltage swing in this example is the difference between the high VS_{H} and low segment voltage VS_{L}, and is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that common line by application of segment voltages along the respective segment lines. The segment voltages may be selected such that actuation is dependent upon the segment voltage applied. When an addressing voltage is applied along a common line, application of one segment voltage will result in a display element voltage within a stability window, causing the display element to remain unactuated. In contrast, application of the other segment voltage will result in a display element voltage beyond the stability window, resulting in actuation of the display element. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having substantially no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation that could occur after repeated write operations of a single polarity.

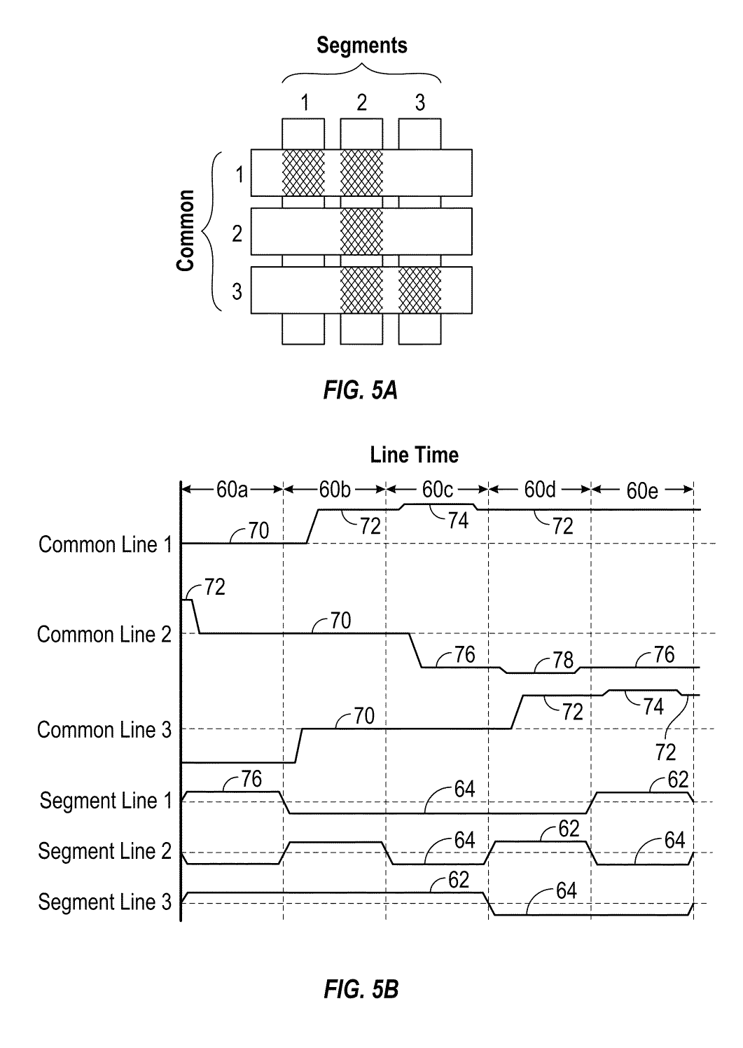

FIG. 5A is an illustration of a frame of display data in a three element by three element array of IMOD display elements displaying an image. FIG. 5B is a timing diagram for common and segment signals that may be used to write data to the display elements illustrated in FIG. 5A. The actuated IMOD display elements in FIG. 5A, shown by darkened checkered patterns, are in a dark-state, i.e., where a substantial portion of the reflected light is outside of the visible spectrum so as to result in a dark appearance to, for example, a viewer. Each of the unactuated IMOD display elements reflect a color corresponding to their interferometric cavity gap heights. Prior to writing the frame illustrated in FIG. 5A, the display elements can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. In some implementations, the segment voltages applied along segment lines 1, 2 and 3 will have no effect on the state of the IMOD display elements, as none of common lines 1, 2 or 3 are being exposed to voltage levels causing actuation during line time 60a (i.e., VC_{REL}−relax and VC_{HOLD}_{_{—}}_{L}−stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the display element voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the display element voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the display element voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state. Then, the voltage on common line 2 transitions back to the low hold voltage 76.

Finally, during the fifth line time 60e, the voltage on common line 1 remains at high hold voltage 72, and the voltage on common line 2 remains at the low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 display element array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the display element voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5A. In some other implementations, voltages applied along common lines or segment lines may vary to account for variations in the actuation and release voltages of different modulators, such as modulators of different colors.

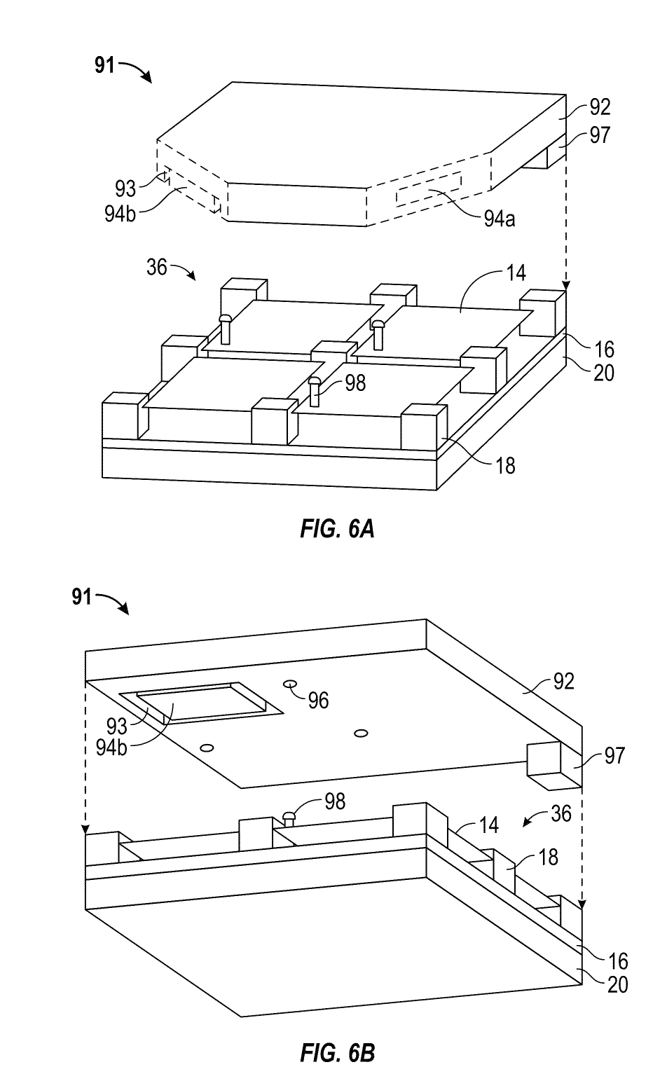

FIGS. 6A and 6B are schematic exploded partial perspective views of a portion of an EMS package 91 including an array 36 of EMS elements and a backplate 92. FIG. 6A is shown with two corners of the backplate 92 cut away to better illustrate certain portions of the backplate 92, while FIG. 6B is shown without the corners cut away. The EMS array 36 can include a substrate 20, support posts 18, and a movable layer 14. In some implementations, the EMS array 36 can include an array of IMOD display elements with one or more optical stack portions 16 on a transparent substrate, and the movable layer 14 can be implemented as a movable reflective layer.

The backplate 92 can be essentially planar or can have at least one contoured surface (e.g., the backplate 92 can be formed with recesses and/or protrusions). The backplate 92 may be made of any suitable material, whether transparent or opaque, conductive or insulating. Suitable materials for the backplate 92 include, but are not limited to, glass, plastic, ceramics, polymers, laminates, metals, metal foils, Kovar and plated Kovar.

As shown in FIGS. 6A and 6B, the backplate 92 can include one or more backplate components 94a and 94b, which can be partially or wholly embedded in the backplate 92. As can be seen in FIG. 6A, backplate component 94a is embedded in the backplate 92. As can be seen in FIGS. 6A and 6B, backplate component 94b is disposed within a recess 93 formed in a surface of the backplate 92. In some implementations, the backplate components 94a and/or 94b can protrude from a surface of the backplate 92. Although backplate component 94b is disposed on the side of the backplate 92 facing the substrate 20, in other implementations, the backplate components can be disposed on the opposite side of the backplate 92.

The backplate components 94a and/or 94b can include one or more active or passive electrical components, such as transistors, capacitors, inductors, resistors, diodes, switches, and/or integrated circuits (ICs) such as a packaged, standard or discrete IC. Other examples of backplate components that can be used in various implementations include antennas, batteries, and sensors such as electrical, touch, optical, or chemical sensors, or thin-film deposited devices.

In some implementations, the backplate components 94a and/or 94b can be in electrical communication with portions of the EMS array 36. Conductive structures such as traces, bumps, posts, or vias may be formed on one or both of the backplate 92 or the substrate 20 and may contact one another or other conductive components to form electrical connections between the EMS array 36 and the backplate components 94a and/or 94b. For example, FIG. 6B includes one or more conductive vias 96 on the backplate 92 which can be aligned with electrical contacts 98 extending upward from the movable layers 14 within the EMS array 36. In some implementations, the backplate 92 also can include one or more insulating layers that electrically insulate the backplate components 94a and/or 94b from other components of the EMS array 36. In some implementations in which the backplate 92 is formed from vapor-permeable materials, an interior surface of backplate 92 can be coated with a vapor barrier (not shown).

The backplate components 94a and 94b can include one or more desiccants which act to absorb any moisture that may enter the EMS package 91. In some implementations, a desiccant (or other moisture absorbing materials, such as a getter) may be provided separately from any other backplate components, for example as a sheet that is mounted to the backplate 92 (or in a recess formed therein) with adhesive. Alternatively, the desiccant may be integrated into the backplate 92. In some other implementations, the desiccant may be applied directly or indirectly over other backplate components, for example by spray-coating, screen printing, or any other suitable method.

In some implementations, the EMS array 36 and/or the backplate 92 can include mechanical standoffs 97 to maintain a distance between the backplate components and the display elements and thereby prevent mechanical interference between those components. In the implementation illustrated in FIGS. 6A and 6B, the mechanical standoffs 97 are formed as posts protruding from the backplate 92 in alignment with the support posts 18 of the EMS array 36. Alternatively or in addition, mechanical standoffs, such as rails or posts, can be provided along the edges of the EMS package 91.

Although not illustrated in FIGS. 6A and 6B, a seal can be provided which partially or completely encircles the EMS array 36. Together with the backplate 92 and the substrate 20, the seal can form a protective cavity enclosing the EMS array 36. The seal may be a semi-hermetic seal, such as a conventional epoxy-based adhesive. In some other implementations, the seal may be a hermetic seal, such as a thin film metal weld or a glass frit. In some other implementations, the seal may include polyisobutylene (PIB), polyurethane, liquid spin-on glass, solder, polymers, plastics, or other materials. In some implementations, a reinforced sealant can be used to form mechanical standoffs.

In alternate implementations, a seal ring may include an extension of either one or both of the backplate 92 or the substrate 20. For example, the seal ring may include a mechanical extension (not shown) of the backplate 92. In some implementations, the seal ring may include a separate member, such as an O-ring or other annular member.

In some implementations, the EMS array 36 and the backplate 92 are separately formed before being attached or coupled together. For example, the edge of the substrate 20 can be attached and sealed to the edge of the backplate 92 as discussed above. Alternatively, the EMS array 36 and the backplate 92 can be formed and joined together as the EMS package 91. In some other implementations, the EMS package 91 can be fabricated in any other suitable manner, such as by forming components of the backplate 92 over the EMS array 36 by deposition.

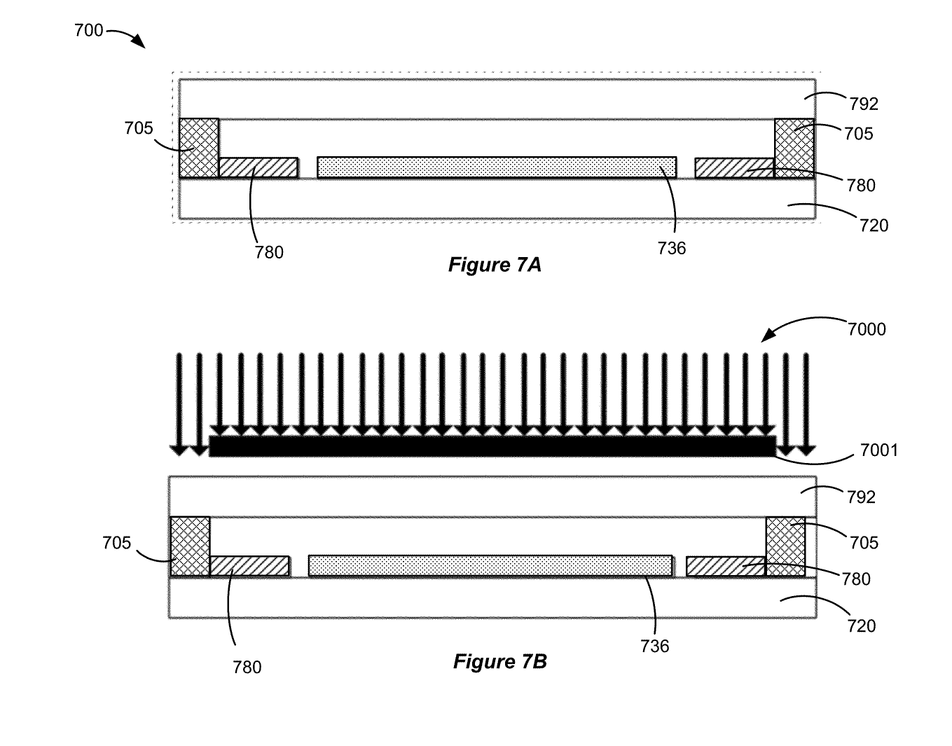

FIGS. 7A and 7B illustrate an elevation view of an arrangement of a partially assembled IMOD display. The partially assembled IMOD display 700 includes an array of display elements, EMS array 736, disposed on a top surface of a transparent substrate 720. The transparent substrate 720 may also be referred to herein as the “transparent front layer”, “first substrate” or “TFT glass”. In the illustrated implementation, TFT circuit layers 780 are likewise disposed on the top (or “inner”) surface of the transparent substrate 720, outside a perimeter of the EMS array 736. The TFT circuit layers 780 may include an integrated TFT driver circuit, for example, which includes TFTs disposed on TFT glass 720. The TFT circuit layers 780 may also include a row driver and/or a data demultiplexing circuit, or components thereof.

During assembly of the IMOD display 700, a backplate 792 (which may also be referred to as the “encapsulation glass” or the “second substrate”) may be secured to transparent substrate 720 and the resulting sandwich-like assembly may be sealed by way of sealant 705. For example, an edge or perimeter of the transparent substrate 720 may be attached and sealed to a corresponding edge or perimeter of the backplate 792 as discussed above in connection with FIGS. 6A and 6B. The sealant may partially or completely encircle the EMS array 736. Ultraviolet (UV) light may be typically used to cure the sealant 705.

The TFT layers 780 may include, for example, amorphous silicon (a-Si), low temperature polysilicon (LTPS) and oxide semiconductor such as InGaZnO, InZnO, InHfZnO, InSnZnO, SnZnO, InSnO, GaZnO, and ZnO. The above-mentioned compositions are sensitive to light irradiation, particularly at UV wavelengths and visible light near blue (λ<500 nm). More particularly, such light may degrade TFT performance and/or reliability, for example, by increasing leakage current and shifting turn-on voltage (Von) to the negative direction.

Referring now to FIG. 7B, one technique to protect the TFT circuit layers 780 from damage during a UV cure of the sealant 705 is illustrated. A shadow mask 7001 is illustrated as being disposed above (or “behind”) the encapsulation glass 792. As illustrated in FIG. 7B, the shadow mask 7001 may be used during cure of the sealant 705, so as to prevent the UV radiation 7000 from reaching the TFT circuit layers 780 and the EMS array 736, while permitting the UV radiation 7000 to reach the sealant 705.

The illustrated approach, however, requires a sophisticated UV irradiation system with precision alignment of the shadow mask 7001. Moreover, the TFTs may still be exposed to some unwanted UV exposure because light diffraction/reflection is possible. Furthermore, the shadow mask 7001 is removed after the curing process, and thus, provides no protection to the TFTs when the TFT glass 720 is exposed to ambient light, backlight or frontlight, for example, when the display is in use later.

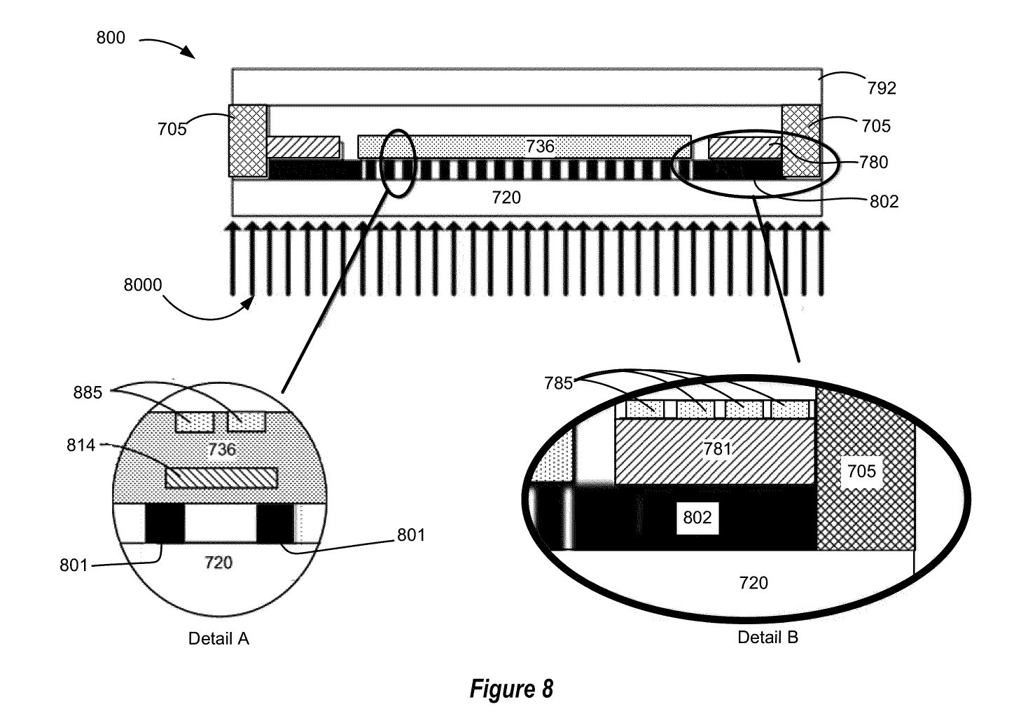

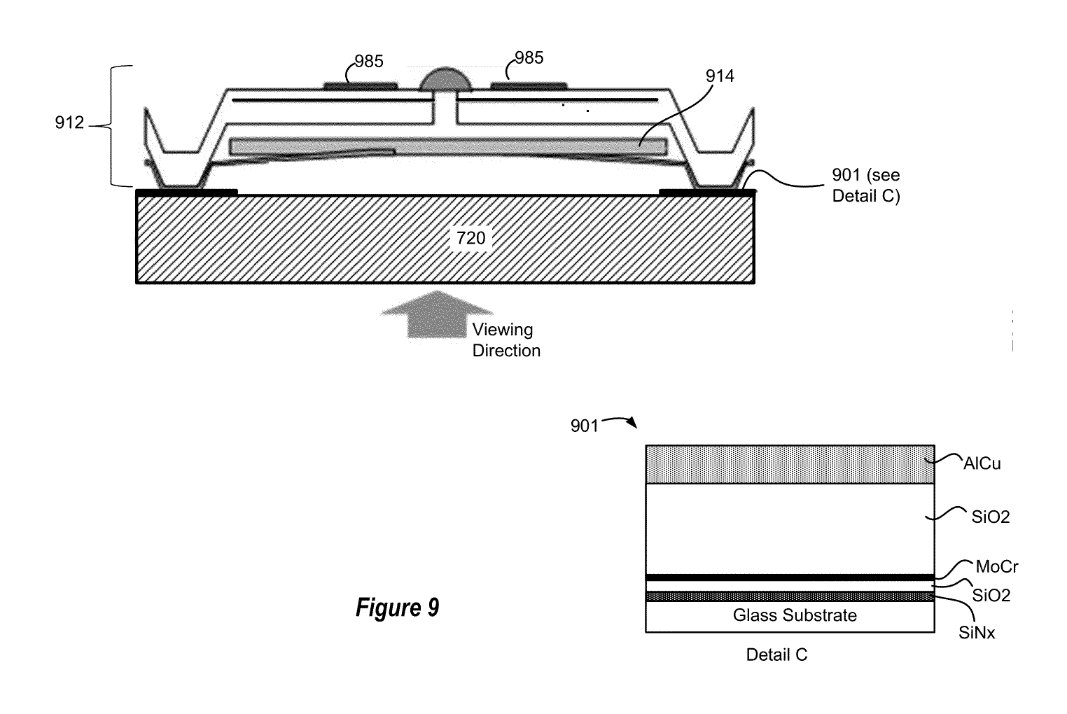

FIG. 8 illustrates an elevation view of an arrangement of a partially assembled IMOD display, according to an implementation. The partially assembled IMOD display 800 may be referred to herein, and in the claims, as a “display assembly”. Similarly to the arrangement described in connection with FIG. 7A, the display assembly 800 may include an array of display elements, EMS array 736, and TFT circuit layers 780 between transparent substrate 720 and backplate 792. TFT circuit layers 780 may be disposed on the inner surface of the transparent substrate 720, outside a perimeter of the EMS array 736, and may include TFT's 785. In addition, the EMS array 736 may include TFT's 885, disposed within the perimeter of the EMS array.

In the illustrated implementation, a black mask arrangement includes a number of black mask (or “black matrix”) stacks (referred to herein as “BM stacks”). The BM stacks may be disposed, on or above the inner surface of the transparent substrate 720, at separate selected locations between the TFTs and one or both of the first substrate and the second substrate. For example, referring to Detail A of FIG. 8, a first number of BM stacks 801 may be disposed proximate to and below reflective movable layers (“mirrors”) 814. In addition, referring now to Detail B of FIG. 8, a second number of BM stacks 802 may be disposed underneath TFT circuit layer 780. As a result, in the illustrated implementation, UV light 8000 may be used to cure the sealant 705 by irradiating the sealant 705 through the TFT glass 720 (i.e., from a user's viewing side of the display) because the BM stacks 801, in cooperation with mirrors 814, prevent UV light from damaging TFTs 885 whereas the BM stacks 802 prevent UV light from damaging TFTs 785.

One or more of the BM stacks 801 and/or 802 may be configured to absorb ambient or stray light. Additionally, the BM stacks 801 and/or 802 may include conductive layers and be configured to function as an electrical bussing layer. Thus, the BM stacks 801 and/or 802 may absorb ambient or stray light and improve the optical response of a display device by increasing the contrast ratio, while also functioning as an electrical bussing layer. In some implementations, the BM stacks 801 and/or 802 may be configured to reflect light of a predetermined wavelength so as to appear as a color other than black. The BM stacks 801 and/or 802 may be electrically coupled to one or more of the display elements and provide one or more electrical paths for voltages applied to one or more of the display elements. The BM stacks 801 and/or 802 may be formed using a variety of methods, including deposition and patterning techniques and include one or more layers. For example, in some implementations, the BM stacks may include a molybdenum-chromium (MoCr) layer that serves as an optical absorber, an insulating layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and wet or dry etching.

In the illustrated implementation, the TFT layer 780 includes insulating layer 781 disposed between the TFTs 785 and the BM stack 802. As a result, a definite nonconductive separation is provided between the TFTs 785 and any conductive layer within the BM stack 802. In some implementations, the insulating layer 781 may be at least 1 μm thick. The insulating layer 781 may include, for example, materials such as SiO₂, SiON, SiN₄, Al₂O₃ and TEOS, which may add insignificant parasitic capacitance. The capacitive coupling between the BM stack 802 and the TFTs 785 may also be reduced by applying a known voltage (for example, ground or one of power supply lines for the TFT circuit) to the BM stack 802.

In addition to providing UV protection during the encapsulation process, it is contemplated that the presently disclosed techniques may provide long term protection to the TFT circuit that might otherwise be caused by a display frontlight and/or ambient light irradiation during use of the display.

FIG. 9 illustrates a cross-section of an IMOD display element according to an implementation. In the illustrated implementation, IMOD display element 912, including a mirror 914, is disposed above transparent substrate 720, and a BM stack 901 is disposed between the IMOD display element 912 and the transparent substrate 720. In cooperation with the mirror 914, the BM stack 901 prevents light, entering the transparent substrate 720 from the viewing direction, from reaching TFTs 985.

In the illustrated implementation, the BM stack 901 is a multilayer arrangement of AlCu, SiO₂, MoCr and SiNx, disposed on a glass substrate as illustrated in Detail C in FIG. 9, but other arrangements are within the contemplation of the present disclosure. In some implementations, a first layer, composed of SiNx and having a thickness in the range of about 10-50 nm, is disposed on the glass substrate; a second layer, composed of SiO₂ and having a thickness in the range of about 5-30 nm, is disposed on the first layer; a third layer, composed of MoCr and having a thickness in the range of about 3-20 nm, is disposed on the second layer; a fourth layer, composed of SiO₂ and having a thickness in the range of about 30-150 nm, is disposed on the third layer; and a fifth layer, composed of AlCu and having a thickness in the range of about 20-100 nm, is disposed on the fourth layer.

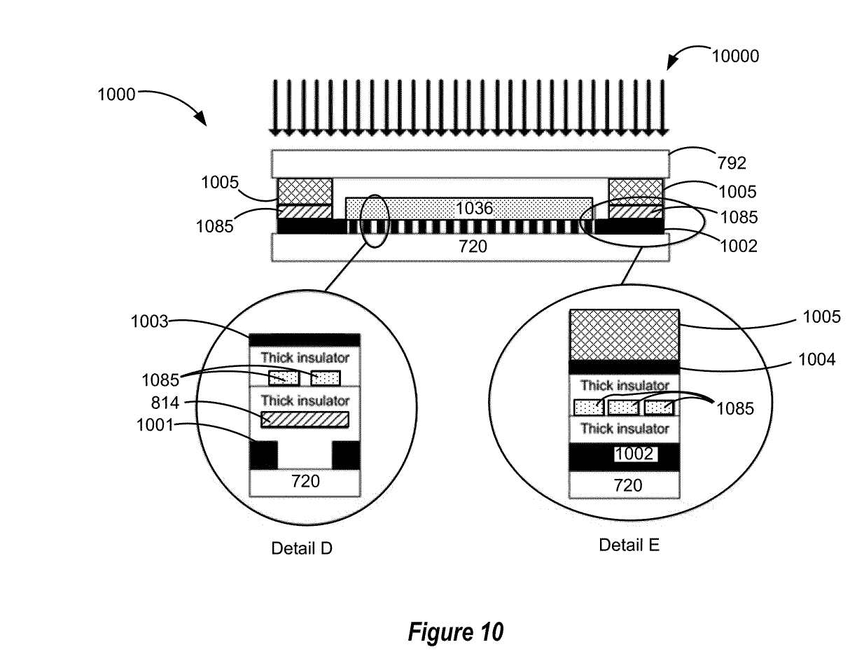

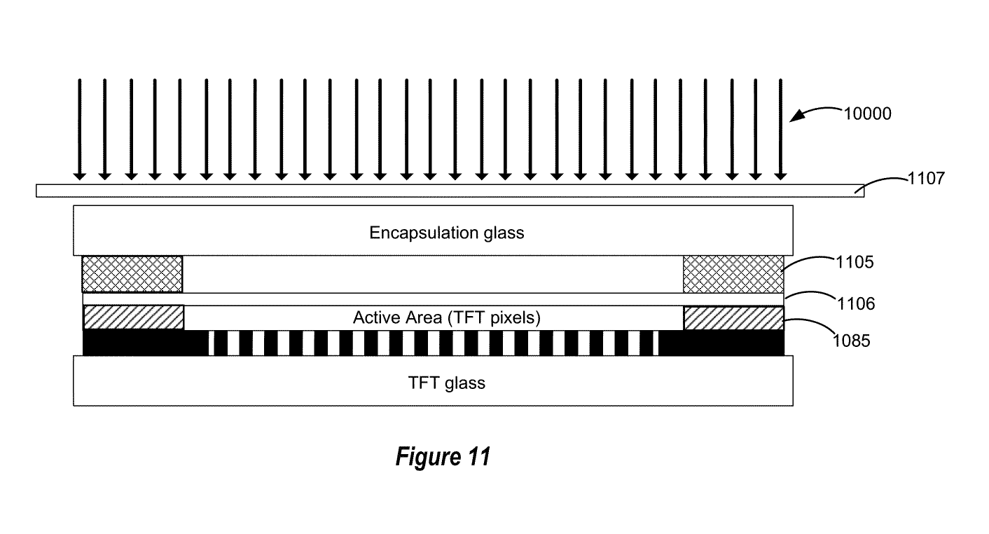

FIG. 10 illustrates an implementation of a partially assembled IMOD display where a black mask arrangement protects TFTs from light impingement. In the illustrated implementation, the black mask arrangement of display assembly 1000 includes, referring to Detail D, a light blocking layer 1003 disposed above TFTs 1085. The light blocking layer 1003 may include a BM or metal layer, for example. A thick insulator (similar to insulating layer 781 of FIG. 8, for example) may be disposed between TFTs 1085 and the light blocking layer 1003. In addition, BM stacks 1001 may be disposed proximate to and below the mirror 814. Similarly to the BM stack 901 described above in connection with FIG. 9, the BM stack 1001 may include a multi-layer stack of metal and non-metal layers.

Referring to Detail E of FIG. 10, in some implementations, the black mask arrangement includes light blocking layer 1004, disposed above the TFTs 1085, in addition to the insulator and BM stack 1002 underneath the TFTs 1085. The light blocking layer 1004 may include a BM or metal layer, for example. A sealant, such as layer 1005, may be disposed over the light blocking layer 1004.

The implementation illustrated in FIG. 10 is effective to prevent light entering the display assembly 1000 from reaching the TFTs 1085 irrespective of whether the light enters the display assembly 1000 through the transparent substrate 720 or through the backplate 792. As a result, application of UV irradiation 10000 through the encapsulation glass (opposite to the direction of viewing) is facilitated, and protection of the TFTs 1085 from light entering from the viewing direction is provided.

FIG. 11 illustrates an implementation of a partially assembled IMOD display where a UV absorbing layer protects the TFTs from light impingement. In the illustrated implementation, a UV absorbing layer 1106, which may be a passivation layer, is disposed over the TFTs 1085, in addition to the BM stack underneath the TFTs 1085. The layer 1106 may be include a UV-absorbing material selected to protect the TFTs from light having a wavelength range between approximately 150 nm to approximately 450 nm. In some implementations, the layer 1106 may include films such as TiOx film or a TiOx—ZrOx hybrid. The UV-absorbing material may be insulating so that power consumption penalty due to parasitic capacitance and field interference to the TFT back-channel is avoided. The UV-absorbing material may have a band-gap energy less than about 2.7 eV. In some implementations, the layer 1106 includes a Si-rich silicon nitride film.

It will be appreciated that sealant 1105 may absorb a certain amount of UV light. Accordingly, in some implementations, a band-pass or low-pass filter 1107 may be configured to block other UV light than the wavelength which is absorbed by the sealant 1105. The filter 1107 may be inserted, for example, between the UV light source and the encapsulation glass. For example, sealant 1105 may be ineffective to absorb UV light having a wavelength shorter than 330 nm but effective to absorb UV light having a wavelength longer than 330 nm. So by filtering out light of a particular range of wavelength, a UV-absorbing passivation layer having a band-gap energy less than about 3.4 eV may be provided. In some implementations, the layer 1106 may include films such as TiOx film or a TiOx—ZrOx hybrid. The implementation illustrated in FIG. 11 facilitates application of UV irradiation through the encapsulation glass (opposite to the direction of viewing) as well as providing protection from light entering from the viewing direction.

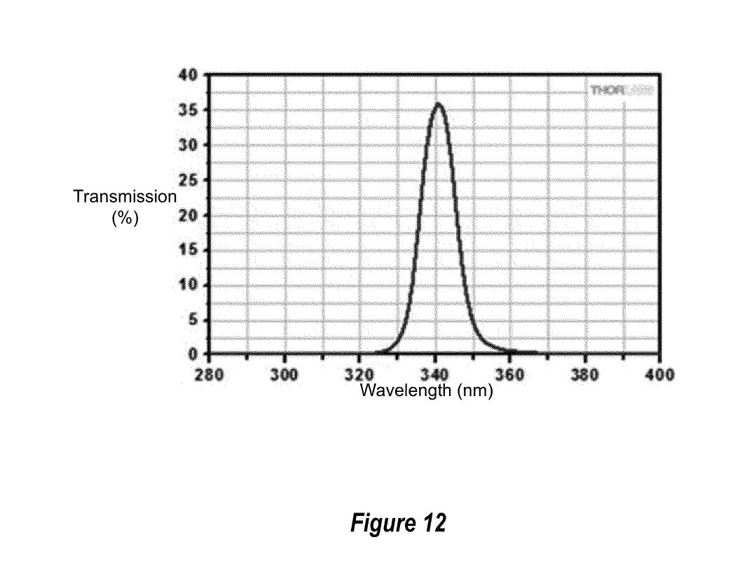

FIG. 12 illustrates an example of performance of a UV light band-pass filter, according to an implementation. The illustrated performance of the UV light band-pass filter shows that light having a wavelength less than about 325 nm or a wavelength greater than about 360 nm is substantially blocked, whereas a substantial amount of light having a bandwidth within the range 325-360 is transmitted through the UV light band-pass filter.

In connection with the implementations described above, provision of UV protection during sealant UV curing was emphasized. It will be appreciated, however, that above disclosed implementations also may be configured to protect the TFT from damage in a self-assembled monolayer (SAM) removal UV process. For example using a Si₃N₄ film whose band-gap is about 5 eV may be effective to prevent damage from UV light having a wavelength in the approximate range of 150 nm to 200 nm.

In some implementations, multiple UV-absorbing insulators (which may be arranged into a stack), each of which can absorb a specific wavelength range, may be used. Alternatively or in addition, any of the techniques described above may be used in combination to achieve a more optimized design. For example at least some routing lines, such as clock and power supply line, for the TFT circuits may be placed underneath the sealant 1005.

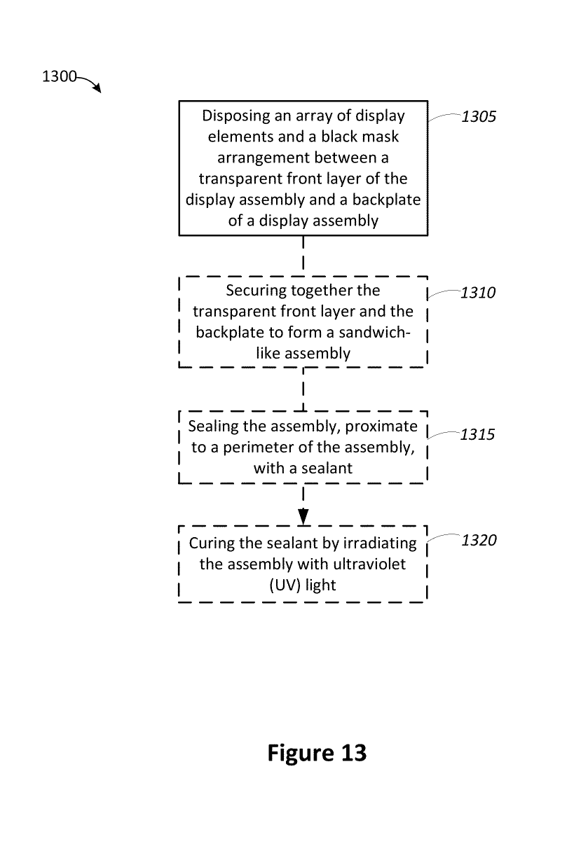

FIG. 13 is a flow diagram illustrating an example of a manufacturing process for a display. In the illustrated implementation, a method 1300 begins with block 1305, which involves disposing an array of display elements and a black mask arrangement transparent front layer of the display assembly and a backplate of a display assembly. As described hereinabove, the display assembly includes TFTs disposed between the transparent front layer and the backplate. The black mask arrangement may be configured to prevent light entering the display assembly from reaching the TFTs. In some implementations, the black mask arrangement includes one or more of BM stacks, BM layers, and metal layers that prevent the light entering the display assembly from reaching the TFTs irrespective of whether the light enters the display assembly through the transparent front layer or through the backplate of the display assembly.

Optionally, in some implementations, the method 1300 continues, at block 1310, with securing together the transparent front layer and the backplate to form a sandwich-like assembly. In such implementations, the sandwich-like assembly may, at block 1315, be sealed. Sealing the assembly may include applying a sealant, proximate to a perimeter of the assembly. The sealant may partially or completely encircle the array of display elements.

In some implementations the method 1300 further includes curing, at block 1320, the sealant by irradiating the assembly with UV light. The UV light may be caused to enter the display assembly when curing the sealant either through the transparent front layer, through the backplate of the display assembly, or both.

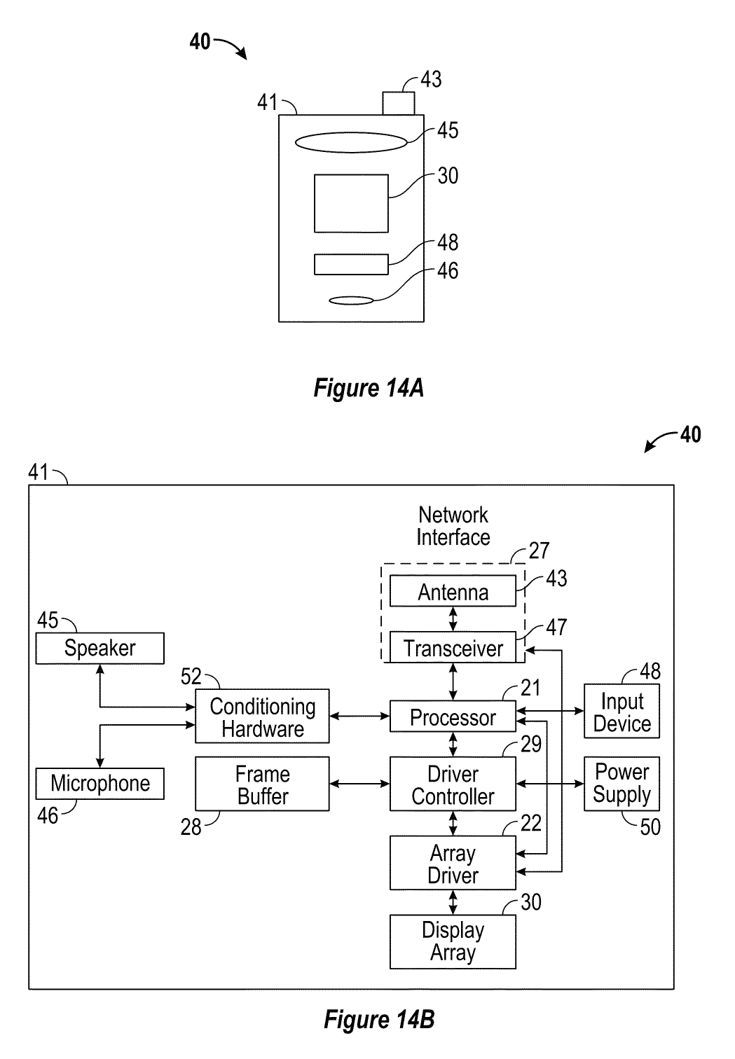

FIGS. 14A and 14B are system block diagrams illustrating a display device 40 that includes a plurality of IMOD display elements. The display device 40 can be, for example, a smart phone, a cellular or mobile telephone. However, the same components of the display device 40 or slight variations thereof are also illustrative of various types of display devices such as televisions, computers, tablets, e-readers, hand-held devices and portable media devices.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD-based display, as described herein.

The components of the display device 40 are schematically illustrated in FIG. 14A. The display device 40 includes a housing 41 and can include additional components at least partially enclosed therein. For example, the display device 40 includes a network interface 27 that includes an antenna 43 which can be coupled to a transceiver 47. The network interface 27 may be a source for image data that could be displayed on the display device 40. Accordingly, the network interface 27 is one example of an image source module, but the processor 21 and the input device 48 also may serve as an image source module. The transceiver 47 is connected to a processor 21, which is connected to conditioning hardware 52. The conditioning hardware 52 may be configured to condition a signal (such as filter or otherwise manipulate a signal). The conditioning hardware 52 can be connected to a speaker 45 and a microphone 46. The processor 21 also can be connected to an input device 48 and a driver controller 29. The driver controller 29 can be coupled to a frame buffer 28, and to an array driver 22, which in turn can be coupled to a display array 30. One or more elements in the display device 40, including elements not specifically depicted in FIG. 14A, can be configured to function as a memory device and be configured to communicate with the processor 21. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the Bluetooth® standard. In the case of a cellular telephone, the antenna 43 can be designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G, 4G or 5G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that can be readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of display elements.

In some implementations, the driver controller 29, the array driver 22, and the display array 30 are appropriate for any of the types of displays described herein. For example, the driver controller 29 can be a conventional display controller or a bi-stable display controller (such as an IMOD display element controller). Additionally, the array driver 22 can be a conventional driver or a bi-stable display driver (such as an IMOD display element driver). Moreover, the display array 30 can be a conventional display array or a bi-stable display array (such as a display including an array of IMOD display elements). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

Thus, improved techniques for protecting TFTs of an IMOD display from damage by visible or ultraviolet light have been disclosed. Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

As used herein, a phrase referring to “at least one of” a list of items refers to any combination of those items, including single members. As an example, “at least one of: a, b, or c” is intended to cover: a, b, c, a-b, a-c, b-c, and a-b-c.

The various illustrative logics, logical blocks, modules, circuits and algorithm processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and processes described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular processes and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium, such as a non-transitory medium. The processes of a method or algorithm disclosed herein may be implemented in a processor-executable software module which may reside on a computer-readable medium. Computer-readable media include both computer storage media and communication media including any medium that can be enabled to transfer a computer program from one place to another. Storage media may be any available media that may be accessed by a computer. By way of example, and not limitation, non-transitory media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the device as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising
a display assembly including an array of display elements disposed between a first substrate and a second substrate;
one or more thin film transistors (TFTs) disposed between the first substrate and the second substrate; and
a black mask arrangement, disposed between the first substrate and the second substrate, the black mask arrangement being configured to prevent light entering the display assembly from reaching the TFTs.

2. The apparatus of claim 1 wherein the first substrate is a transparent front layer of the display assembly and the second substrate is a backplate of the display assembly.

3. The apparatus of claim 2, wherein at least a first portion of the TFTs is disposed on an inner surface of the transparent front layer, outside a perimeter of the array of display elements.

4. The apparatus of claim 2, wherein the display assembly includes an ultraviolet (UV) absorbing passivation layer disposed between the TFTs and the backplate.

5. The apparatus of claim 1, wherein the black mask arrangement includes a plurality of black mask (BM) stacks, at least a first BM stack configured to protect the TFTs from light entering the display assembly through the first substrate.

6. The apparatus of claim 5, wherein the black mask arrangement includes a light blocking layer configured to protect the TFTs from light entering the display assembly through the second substrate.

7. The apparatus of claim 6, wherein the light blocking layer includes a metal layer.

8. The apparatus of claim 7, wherein the display assembly includes an insulating layer between at least one BM stack and at least a portion of the TFTs.

9. The apparatus of claim 1, wherein the array of display elements includes an array of interferometric modulator (IMOD) display elements.

10. The apparatus of claim 1, wherein the black mask arrangement is configured to prevent the light entering the display assembly from reaching the TFTs irrespective of whether the light enters the display assembly through the first substrate or through the second substrate of the display assembly.

11. The apparatus of claim 1, wherein the first substrate and the second substrate are secured together to form a sandwich-like assembly, the assembly being sealed, proximate to a perimeter of the assembly, by way of a sealant.

12. The apparatus of claim 11, wherein the display assembly includes a filter disposed between an ultraviolet (UV) light source and the TFTs, the filter being configured to filter out UV light other than a wavelength which is absorbed by the sealant.

13. The apparatus of claim 11, wherein the sealant at least partially encircles the array.

14. The apparatus of claim 1, wherein:
the black mask arrangement includes a number of black mask (BM) stacks that are disposed at separate selected locations between the TFTs and one or both of the first substrate and the second substrate; and the separate selected locations are selected with reference to respective locations of portions of the TFTs.

15. The apparatus of claim 14, wherein:
the array of display elements includes an array of interferometric modulator (IMOD) display elements, each IMOD display element including a respective reflective movable layer; and
at least one of the BM stacks is disposed, between the IMOD display elements and the first substrate, proximate to one of the respective reflective movable layers.

16. The apparatus of claim 15, wherein the BM stacks, in cooperation with the reflective movable layers, prevent light, having passed through the first substrate, from reaching the TFTs.

17. The apparatus of claim 15, wherein at least a portion of the TFTs is disposed between the reflective movable layers and the second substrate.

18. The apparatus of claim 14, wherein the BM stacks include conductive layers that are configured to function as an electrical bussing layer.

19. A method for fabricating a display assembly, the method comprising:
disposing an array of display elements and a black mask arrangement between a transparent front layer of the display assembly and a backplate of the display assembly, the display assembly including one or more thin film transistors (TFTs) disposed between the transparent front layer and the backplate; and the black mask arrangement being configured to prevent light entering the display assembly from reaching the TFTs.

20. The method of claim 19, further comprising:
securing together the transparent front layer and the backplate to form a sandwich-like assembly;
sealing the assembly, proximate to a perimeter of the assembly, with a sealant; and
curing the sealant by irradiating the assembly with ultraviolet (UV) light.

21. The method of claim 19, further comprising performing an ultraviolet self-assembled monolayer removal UV process.

22. The method of claim 20, wherein:
the black mask arrangement includes a number of black mask (BM) stacks that are disposed at separate selected locations between the TFTs and one or both of the first substrate and the second substrate;
the array of display elements includes an array of interferometric modulator (IMOD) display elements each IMOD display element including a respective reflective movable layer; and
at least one of the BM stacks is disposed, between the IMOD display elements and the first substrate, proximate to one of the reflective movable layers.

23. An apparatus comprising:
a display assembly including an array of interferometric modulator (IMOD) display elements disposed between a transparent front layer of the display assembly and a backplate of the display assembly, the display assembly including one or more thin film transistors (TFTs) disposed between the transparent front layer and the backplate; and
an ultraviolet (UV) light absorbing layer disposed between the TFTs and the backplate, the UV light absorbing layer being configured to absorb a portion of UV light within a selected wavelength range.

24. The apparatus of claim 23, wherein the UV-absorbing layer has a band-gap energy less than about 2.7 eV.

25. The apparatus of claim 23, wherein the UV-absorbing layer includes one or more of a Si-rich silicon nitride film, a TiOx film, and a TiOx—ZrOx hybrid film.

26. The apparatus of claim 23, wherein the UV-absorbing layer is an insulator.

27. An apparatus comprising:
a display assembly including an array of interferometric modulator (IMOD) display elements disposed between a transparent front layer of the display assembly and a backplate of the display assembly, the array of display elements including one or more thin film transistors (TFTs) disposed between the transparent front layer and the backplate; and
a black mask arrangement, disposed between the first substrate and the second substrate, the black mask arrangement being configured to prevent light entering the display assembly from reaching the TFTs, irrespective of whether the light enters the display assembly through the transparent front layer of the display assembly or through the backplate of the display assembly.

28. The apparatus of claim 27, wherein the black mask arrangement includes (i) a plurality of black mask (BM) stacks, at least a first BM stack configured to protect the TFTs from light entering the display assembly through the first substrate; and (ii) a light blocking layer configured to protect the TFTs from light entering the display assembly through the second substrate.

29. The apparatus of claim 27, wherein the display assembly includes a filter disposed between an ultraviolet (UV) light source and the TFTs, the filter being configured to filter out UV light other than a wavelength which is absorbed by the sealant.

30. The apparatus of claim 27, wherein
each IMOD display element includes a respective reflective movable layer; and
at least one of the BM stacks is disposed, between the IMOD display elements and the first substrate, proximate to one of the respective reflective movable layers.
